(19) United States
(12) Patent Application Publication
(10) Pub. No.: US 2003/0064599 A1
(43) Pub. Date: Apr. 3, 2003

(54) Pattern forming method

(76) Inventors: Ichiro Miki, Tokyo (JP); Takeshi Matsunuma, Tokyo (JP); Kiyoshi Maeda, Hyogo (JP)

Correspondence Address: BURNS DOANE SWECKER & MATHIS L L P, POST OFFICE BOX 1404, ALEXANDRIA, VA, 22313-1404, US

(21) Appl. No.: 10/214,761

(22) Filed: Aug. 9, 2002

(30) Foreign Application Priority Data
Sep. 28, 2001 (JP) 2001-302557

(51) Int. Cl. H01L 21/311

(52) U.S. Cl. 438/694

(57) ABSTRACT

In the production of semiconductor devices, when forming a predetermined pattern within a to-be-processed material such as interlayer film, photoresist is first applied over the material, then exposed, and developed, to thereby form a resist film having the predetermined pattern shape on the material. The material is next etched to a predetermined depth through the resist film as a mask. The resist film is removed and then the material is further etched to form the predetermined pattern within the material. Then, an etching stopper film has been formed at a predetermined depth, the etching is continued until the etching reaches the etching stopper film, and then the photoresist is removed. Additionally, an antireflection layer is used as the etching stopper film.

### BACKGROUND OF THE INVENTION

1. Field of the Invention

The present invention relates to a pattern forming method in microfabrication when manufacturing semiconductor devices having semiconductor integrated circuits and so on. More particularly, the present invention relates to a pattern forming method with which a pattern shape can be positively controlled when patterning.

2. Description of the Prior Art

In general, when manufacturing semiconductor devices, various patterns (contact hole pattern, wiring pattern, and trench pattern, for instance) are formed. On the formation of these patterns, lithography technology is typically used. A resist (photoresist) pattern having a predetermined pattern shape is formed, and then dry etching, for instance, is done through use of this resist pattern as a mask to form a pattern within a to-be-processed material (interlayer film, for instance).

In the dry etching process, depending on the depth of etching, when the material has a sufficiently high selective (etching) ratio to the resist, the resist pattern shape can be closely (precisely) transferred to the to-be-processed material. However, the higher the degree of integration of semiconductor devices is, the finer the pattern thereof is (the smaller the pattern pitch thereof is). When the pattern pitch is small, the resist thickness must be reduced in order to increase the resolution. When the resist thickness is small, the resist pattern shape cannot be occasionally precisely transferred to the to-be-processed material because the material does not have sufficiently high selective (etching) ratio to the resist.

As mentioned above, when the pattern is made very fine or microfabricated, the resist thickness must be reduced. However, the reduction of the resist thickness gives rise to lack of the etching selectivity. For instance, when the pattern of a contact hole is formed as a pattern within the to-be-processed material by dry etching, there has been a drawback that the size of the contact hole in the upper part of the hole becomes larger than a desired shape.

In addition, when the wiring pattern is formed within the to-be-processed material by dry etching, there has been a drawback that the wiring pattern becomes larger than the desired pattern shape, and as a result the wiring pattern having the desired size cannot be formed. Additionally, because in general the resist contains carbon (C), when the wiring pattern is formed by dry etching, the longer the etching time is, the higher the possibility of the penetration of the carbon into the to-be-processed material is. As a result, there is also a drawback of deterioration of the shape of the wiring pattern. For instance, there has been a drawback that unevenness develops on the edge of the wiring pattern, and thereby the wiring pattern varies in size.

Additionally, when a trench is formed within the to-be-processed material by dry etching, there also arises a similar disadvantage to that found in the formation of the contact hole and in the formation of the wiring pattern. For instance, there has been a drawback that a similar disadvantage to that found in the formation of the contact hole and in the formation of the wiring pattern when a trench is formed within an insulation film in so-called damascene method in which a trench is formed within a to-be-processed material, the trench is filled with copper which serves as a wiring material by means of plating and so on, and then an excess copper thin film deposited outside the trench is removed by means of chemical and mechanical polishing (CMP), to thereby form wirings.

In order to avoid the above-mentioned disadvantage, the optimization of the etching conditions and manufacturing apparatus for the optimizing control are required. As a result, there has also existed a drawback that the cost becomes large.

### SUMMARY OF THE INVENTION

The present invention has been accomplished to solve the above-mentioned drawbacks. An object of the present invention is to provide a pattern forming method capable of precisely transferring a fine pattern shape to a to-be-processed material by etching.

Another object of the present invention is to provide a pattern forming method capable of transferring a fine pattern shape to a to-be-processed material at low cost.

According to a first aspect of the present invention, there is provided a pattern forming method used when forming a predetermined pattern within a to-be-processed material, the method including: a first step of forming a resist film having a predetermined pattern shape on the material; a second step of etching the material to a predetermined depth through use of the resist film as a mask; and a third step of removing the resist film and then further etching the material to form the predetermined pattern within the material.

Therefore, the pattern shape can be precisely controlled within the predetermined shape even if the resist film is made thinner so as to microfabricate pattern configurations. That is to say, the pattern configurations can be precisely transferred to a to-be-processed material by etching. What is more, because the optimization of the etching condition, the specific manufacturing apparatus therefor, and the like are not required during the etching, that is, it is only essential to carry out the etching by means of common etching methods, fine pattern configurations can be also transferred to a to-be-processed material at low cost.

According to a second aspect of the present invention, there is provided a pattern forming method used when forming a predetermined pattern within a to-be-processed material having a first to-be-processed material and a second to-be-processed material formed over the first material, the method including: a first step of forming a resist film having a predetermined pattern on the second material; a second step of etching the second material through use of the resist film as a mask to a predetermined depth thereof; a third step of removing the resist film and then further etching the second material; and a fourth step of etching the first material through use of the second material as a mask to form the predetermined pattern within the material.

Therefore, a fine pattern can be precisely formed within the to-be-processed material by etching even if the resist film is made thinner.

According to a third aspect of the present invention, there is provided a pattern forming method wherein a first pattern is formed within a first to-be-processed material, a second pattern is formed within a second to-be-processed material formed on the first material, and the first pattern and the second pattern are arranged to be connected, the method including: a first step of forming an etching stopper film over the first material; a second step of forming a first resist film having the first pattern shape on the etching stopper film; a third step of etching the etching stopper film through use of the first resist film as a mask; a fourth step of removing the first resist film and then forming the second material over the etching stopper film; a fifth step of forming a second resist film having the second pattern shape on the second material; a sixth step of etching the second material to a predetermined depth thereof through use of the second resist film as a mask; and a seventh step of removing the second resist film, then further etching the second material and simultaneously etching the first material, to thereby form the second pattern within the second material and form the first pattern within the first material.

Therefore, not only a fine pattern shape can be precisely formed within a to-be-processed material by etching whereas a resist film is made thinner, but also an opening can be formed in a self-aligning manner by an etching stopper film.

### BRIEF DESCRIPTION OF THE DRAWINGS

FIGS. 1A-1C illustrate a flow chart of the pattern forming method according to Embodiment 1 of the present invention;

FIGS. 2A-2C illustrate a flow chart of the pattern forming method according to Embodiment 2 of the present invention;

FIGS. 3A-3D illustrate a flow chart of the pattern forming method according to Embodiment 3 of the present invention;

FIGS. 4A-4E illustrate a flow chart of the pattern forming method according to Embodiment 4 of the present invention;

FIGS. 5A-5C illustrate a flow chart of the pattern forming method according to Embodiment 5 of the present invention;

FIG. 6 is a figure for illustrating self-alignment opening in the pattern forming method shown in FIG. 5; and

FIG. 7 is a figure for illustrating the state in which the edge part of a trench is rounded in the pattern forming method shown in FIGS. 5A-5C.

### DETAILED DESCRIPTION OF THE PREFERRED EMBODIMENTS

An embodiment of the present invention will be described below.

Embodiment 1

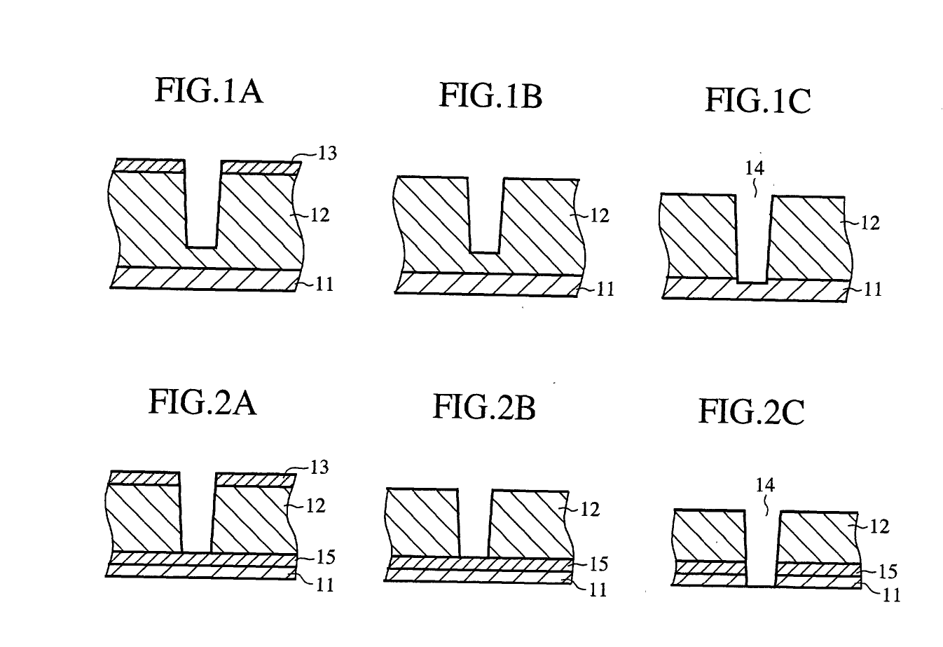

Referring to FIGS. 1A-1C, the formation of a contact hole having a predetermined pattern within interlayer film 12 (to-be-processed material, for instance, insulation film) formed over underlayer film 11 will next be described.

First of all, photoresist 13 having a predetermined thickness is applied over interlayer film 12, and then photoresist 13 is exposed through use of a predetermined pattern and developed, to thereby form a mask pattern having a predetermined pattern shape. Then dry etching is done halfway through interlayer film 12 (to a predetermined depth) through use of photoresist 13 as a mask (FIG. 1A). Photoresist 13 is removed (FIG. 1B), and then the etching is further continued, to thereby form contact hole 14 reaching underlayer film 11 within interlayer film 12 (FIG. 1C).

At that time, whereas the surface of interlayer film 12 is also etched, the thickness of interlayer film 12 has been previously determined corresponding to the depth of the hole (e.g., hole rate) and the etching rate at the surface of interlayer film 12. (That is, the thickness of interlayer film 12 before etching is previously determined such that insulation between underlayer 11 and upper layer (not shown) located over interlayer 12 is maintained after forming the contact hole. In other words, the thickness of interlayer film 12 before etching is previously determined depending on the proportion between the etching amount contributed by etching interlayer film 12 to a predetermined depth through use of photoresist 13 as a mask and the etching amount contributed by etching interlayer film 12 after removing photoresist 13.)

As mentioned above, according to Embodiment 1, even if photoresist 13 is made thinner in order to microfabricate a hole pattern, photoresist 13 is removed before photoresist 13 itself has been etched off and then the etching is continued. That is, interlayer film 12 of the to-be-processed material is etched to the predetermined depth through use of photoresist 13 as a mask, and then the etching is further continued after removing photoresist 13. Thus, the contact hole is not larger than a desired shape in its upper part even if photoresist 13 is made thinner. As a result, the formation of the hole can be controlled at the desired shape with favorable accuracy.

In addition, when underlayer film 11 is metallic, for instance, underlayer film 11 inevitably reacts with photoresist 13 to produce a reaction product in the etching process. However, as mentioned above, because interlayer film 12 is etched to the predetermined depth, and then the etching is further continued after removing photoresist 13, a time when underlayer film 11 and photoresist 13 react with each other is shortened, and as a result, the production of the reaction product can be suppressed. Therefore, the labor of the post-processing (the removal of the reaction product) after the formation of the hole can be reduced or omitted.

Embodiment 2

In FIGS. 2A-2C, the same components as those of FIGS. 1A-1C are designated by the same reference numerals. In the example shown in the figures, etching stopper film 15 (nitride film (SiN) or polysilicon film, for instance) is formed over underlayer film 11 (first to-be-processed material), and interlayer film 12 (second to-be-processed material) is formed over etching stopper film 15 (Further, an upper layer film (not shown) is occasionally formed over interlayer film 12.). When contact hole 14 is formed within interlayer film 12 of the second to-be-processed material, first of all photoresist 13 having a predetermined thickness is applied over interlayer film 12, and then photoresist 13 is exposed through use of a predetermined pattern and developed, to thereby form a mask pattern having a predetermined pattern shape.

Interlayer film 12 is dry-etched to etching stopper film 15 through use of photoresist 13 as a mask (FIG. 2A). Photoresist 13 is removed (FIG. 2B), and then the etching is further continued, to thereby form contact hole 14 reaching underlayer film 11 through etching stopper film 15 within interlayer film 12 (and etching stopper film 15) (FIG. 2C). At that time, whereas the surface of interlayer film 12 is also etched, the thickness of interlayer film 12 has been determined corresponding to the depth of the hole (the hole rate, for instance) and the etching rate at the surface of interlayer film 12.

In addition, interlayer film 12 may serve as the only one to-be-processed material, that is, the etching stopper film may be provided within interlayer film 12 by partitioning interlayer film 12 into two layers. In other words, interlayer film 12 may be divided into two layers, and the etching stopper film may exist between the layers.

As mentioned above, according to Embodiment 2, because interlayer film 12 is etched to etching stopper film 15, then photoresist 13 is removed, and thereafter the etching is continued, not only an advantageous effect similar to Embodiment 1 is obtained, but also it is essential only that photoresist 13 be removed after interlayer film 12 was etched to etching stopper film 15. As a result, the timing of the removal of the photoresist 13 can be easily known.

Moreover, when an antireflection film is used as etching stopper film 15, the reflection from the underlayer film can be prevented in the exposure of photoresist 13. As a result, deleterious effects (abnormal pattern shapes) due to the reflection light can be avoided on formation of the mask pattern (resist pattern).

Embodiment 3

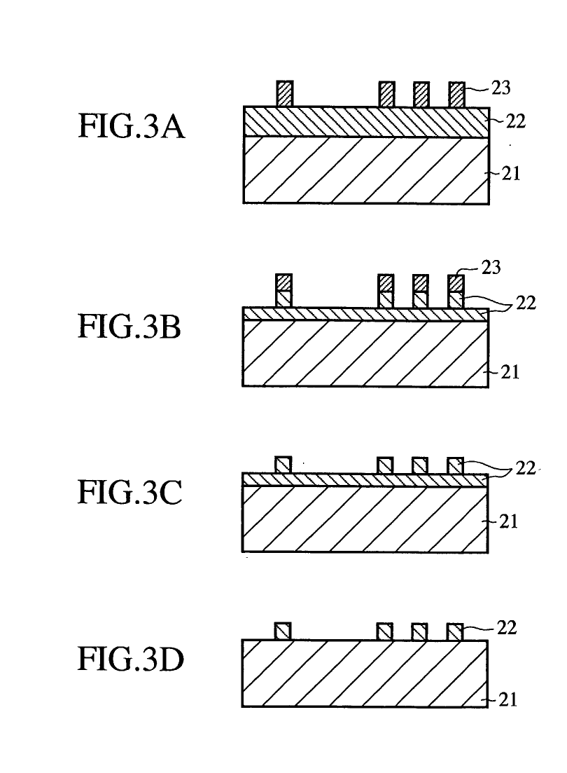

Referring to FIGS. 3A-3D, an example of forming a wiring pattern within to-be-processed material 22 (polysilicon layer, for instance) formed over substrate 21 will next be described.

First of all, photoresist 23 having a predetermined thickness is applied over polysilicon layer 22 (having a thickness of 100 nm, for instance) formed over substrate 21, and then photoresist 23 is exposed through use of a predetermined pattern and developed, to thereby form a mask pattern having a wiring pattern (FIG. 3A). Then, polysilicon layer 22 is dry-etched halfway through the layer (to a predetermined depth thereof) through use of photoresist 23 as a mask. In other words, half-etching is done (FIG. 3B).

At that time, the etching was performed under the conditions where, for instance, etcher: an ECR (Electron Cyclotron Resonance) etcher, pressure: 0.4 Pa, RF: 50 W, μ-wave: 400 W, feed gases: Cl₂/O₂=70/10 sccm, and etching rate: 60 nm/minute. Photoresist 23 was removed (FIG. 3C), and then the etching was further continued until the substrate 21 was exposed all over the surface through a wiring pattern (until the wiring pattern was formed within polysilicon layer 22, in other words) (FIG. 3D). At that time, the etching was performed under the conditions where etcher: an ECR etcher, pressure: 0.4 Pa, RF: 50 W, μ-wave: 400 W, feed gas: Cl₂ 60 sccm, and etching rate: 60 nm/minute.

As mentioned above, when forming the wiring pattern within polysilicon layer 22 that is the to-be-processed material, the etching is carried out to the state shown in FIG. 3B, in other words the etching is done halfway through polysilicon layer 22, then photoresist 23 is removed, and thereafter the etching is performed all over the surface of polysilicon layer 22. Thereby, because the edge part of the wiring pattern (its corner part) is also exposed to plasma, the edge part is rounded. When polysilicon layer 22 is etched all over the surface thereof, an opening ratio of 100 percent at the wafer is obtained regardless of the shape of the wiring pattern.

As mentioned above, according to Embodiment 3, when forming a fine wiring pattern within the to-be-processed material, a time of the etching through use of photoresist 23 as a mask is shortened, even if photoresist 23 is thinner. As a result, the etching of photoresist 23 itself is not reduced, and thereby the shape of the wiring pattern is maintained or not broken. That is to say, because it is possible to make photoresist 23 thin immediately before the shape of the wiring pattern is devastated, a fine wiring pattern can be easily formed.

In addition, as previously stated, photoresist 23 is removed, and then the etching is performed all over the surface of polysilicon layer 22 that is the to-be-processed material. Thereby, because the edge part of the wiring pattern (its corner part) is also exposed to plasma, the edge part is rounded. As a result, it also becomes easy to bury the interlayer film formed between wirings, for instance.

Moreover, because photoresist 23 is removed and then the etching is further continued, carbon is not carried into the polysilicon layer, and so on from photoresist 23. As a result, unevenness or roughness formed on the edge of the wiring pattern is reduced compared with the case where the overall process of etching is done through use of photoresist 23 as a mask.

Additionally, as described above, because the opening ratio at the wafer (substrate) is 100 percent, the difference of the etching rate caused by the difference of the pattern within the mask pattern or within the wafer surface can be easily controlled. As a result, the etching amount of the underlayer (substrate) can be easily controlled.

Embodiment 4

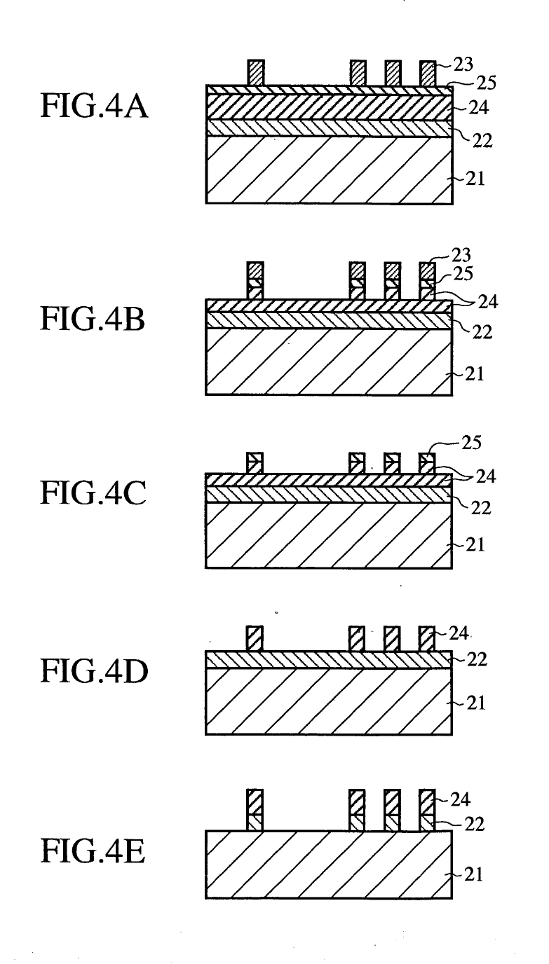

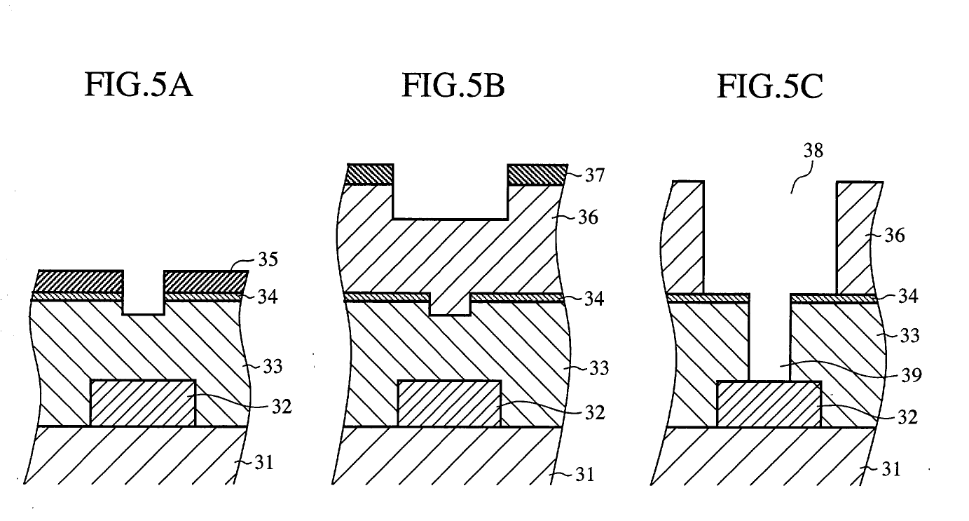

In FIGS. 4A-4E, the same components as those of FIGS. 3A-3C are designated by the same reference numerals. In the example shown in the figures, polysilicon layer 22 (first to-be-processed material) having a thickness of 50 nm formed over substrate 21, and oxide film 24 (SiO₂, second to-be-processed material) having a thickness of 90 nm is formed over polysilicon layer 22. Nitride film (SiN) 25 having a thickness of 48 nm is formed over oxide film 24, and nitride film 25 serves as an antireflection film. Oxide film 24 severs as a mask, as described later, when polysilicon layer 22 is etched.

First of all, photoresist 23 having a predetermined thickness is applied over polysilicon layer 22, and then photoresist 23 is exposed through use of a predetermined wiring pattern and developed, to thereby form a mask pattern having a wiring pattern (FIG. 4A). At that time, the reflection from the film located as the underlayer is prevented by nitride film 25, and thereby a fine resist pattern is precisely formed. After that, oxide film 24 is dry-etched halfway through the film (to a predetermined depth) through use of photoresist 23 as a mask. In other words, half-etching is done (FIG. 4B).

At that time, the oxide film was etched under the conditions where, for instance, etcher: a parallel-plates etcher, pressure: 26 Pa, RF: 1,100 W, feed gases: CF₄/Ar/O₂=60/800/20 sccm, and etching rate: 60 nm/minute. Photoresist 23 is removed (FIG. 4C), and then oxide film 24 is etched to the end under the condition where nitride film 25 and oxide film 24 are exposed all over the surface (FIG. 4D). Thereby, the antireflection film, nitride film 25 in a word is completely removed.

The etching shown in FIG. 4D was performed under the conditions where etcher: a dual frequency parallel-plates etcher, pressure: 2.7 Pa, RF: 1,000W (Top)/800W (Bottom), feed gases: CF₄/Ar/O₂=50/400/10 sccm, and etching rate: 60 nm/minute.

After that, polysilicon layer 22 was etched through use oxide film 24 having a formed (transferred) wiring pattern as a mask, to thereby form the wiring pattern within oxide film 24 and polysilicon layer 22 (FIG. 4E). At that time, the etching was performed under the conditions where etcher: an ECR etcher, pressure: 0.4 Pa, RF: 30 W, μ-wave: 400 W, feed gases: Cl₂/HBr/O₂=30/70/5 sccm, and etching rate: 60 nm/minute.

As mentioned above, when the wiring pattern is formed within oxide film 24 and polysilicon layer 22 that are to-be-processed materials, the etching is done to a state shown in FIG. 4B, that is, halfway through oxide film 24, then photoresist 23 is removed, subsequently oxide film 24 is etched to the end, and then polysilicon layer 22 is further etched through use of oxide film 24 as a mask. Thereby, because the edge part of the wiring pattern is exposed to plasma, the edge part becomes round. After that, when nitride film 25 and oxidation film 24 were exposed, polysilicon layer 22 is etched, to thereby obtain an open/close ratio of 100 percent at the wafer regardless of the shape of the wiring pattern.

As described above, according to Embodiment 4, when a fine wiring pattern is formed within the to-be-processed material, a time of etching through use of photoresist 23 as a mask can be shortened, even if photoresist 23 is thin. As a result, the etching of photoresist 23 itself is reduced, and thereby the shape of the wiring pattern is not devastated. That is to say, because it is possible to make photoresist 23 thin immediately before the shape of the wiring pattern is devastated, a fine wiring pattern can be easily formed.

In addition, as previously stated, photoresist 23 is removed, then oxide film 24 that is the to-be-processed material is etched to the end, and after that, polysilicon layer 22 is etched through use of oxide film 24 as a mask. Thereby, the edge part of the wiring pattern is also exposed to plasma, and rounded. As a result, it also becomes easy to bury the interlayer film formed between wirings, for instance.

Moreover, because photoresist 23 is removed and then the etching is further done, carbon is not carried into the oxide film and the polysilicon layer from photoresist 23. As a result, unevenness or roughness formed on the edge of the wiring pattern is reduced compared with the case where the over all process of etching is performed through use of photoresist 23 as a mask. Particularly, it is possible to markedly improve the oxidation film where the unevenness formed on the edge of the wiring pattern often becomes a problem.

Additionally, as described above, because the opening ratio at the wafer (substrate) is 100 percent, the difference of the etching rate caused by the difference of the pattern within the mask pattern or within the wafer surface can be easily controlled. As a result, the etching amount of the underlayer (substrate) can be easily controlled.

Moreover, the nitride film (antireflection film) is required when forming the photoresist pattern is removed by the etching done after the photoresist was removed. As a result, an additional process to remove the antireflection film is not required particularly.

Embodiment 5

Referring to FIGS. 5A-5C, the formation of a hole and a trench when manufacturing the semiconductor device will next be described.

In FIG. 5A, interlayer insulation film 31 of plasma TEOS, and the like is formed over the semiconductor substrate (not shown) arranged to have elements. Metallic film 32 (e.g., Cu film) is deposited on interlayer insulation film 31 by means of P-CVD, for instance. Further, interlayer insulation film 33 of plasma TEOS and so on is formed over metallic film 32, and then stopper film 34 (e.g., P-SiN) is deposited over interlayer insulation film 33 by means of P-CVD.

Subsequently, thin-film photoresist 35 is applied over stopper film 34, and then photoresist 35 is exposed through use of a predetermined hole pattern (narrow-pitch hole pattern, a first pattern), and developed, to thereby form a mask pattern having a hole pattern. After that, stopper film 34 is anisotropicly etched by use of fluorocarbon gas through use of photoresist 35 as a mask (FIG. 5A). At that time, since only stopper film 34 is etched, the etching can be sufficiently precisely done even if photoresist 35 is thin.

Photoresist 35 is removed, and then interlayer insulation film 36 of plasma TEOS and so on is formed in such a manner that the insulation film covers remaining stopper film 34. Then, thin-film photoresist 37 is applied over interlayer insulation film 36, and then photoresist 37 is exposed through use of a predetermined trench pattern (narrow-pitch trench pattern, a second pattern) and developed, to thereby form a mask pattern having a trench pattern. Interlayer insulation film 36 is etched halfway through the film (to a predetermined depth thereof) by use of fluorocarbon gas through use of photoresist 37 as a mask (FIG. 5B). At that time, since interlayer insulation film 36 is only etched halfway through the film, the etching can be sufficiently precisely performed even if photoresist 37 is thin.

After that, photoresist 37 is removed, and then remaining interlayer insulation film 36 and interlayer insulation film 33 are etched by use of fluorocarbon gas. At that time, an etching condition where the selective etching ratio between stopper film 34 and interlayer insulation films 36 and 33 is high is used. For this reason, as shown in FIG. 5C, trench 38 corresponding to the narrow-pitch trench pattern is formed within interlayer insulation film 36 and simultaneously hole 39 connected with trench 38 is formed within interlayer insulation film 33. Hole 39 reaches metallic film 32 (lower wiring layer).

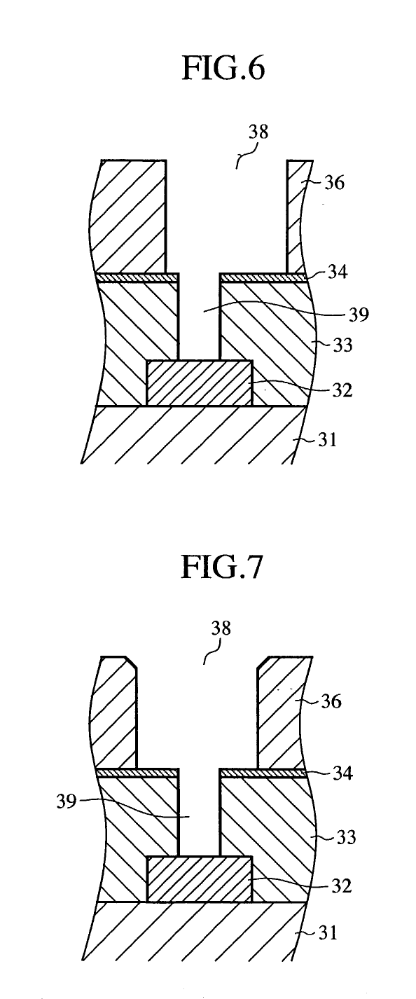

As mentioned above, when trench 38 and hole 39 are formed, stopper film 34 is hardly etched as long as the condition where the selective etching ratio between stopper film 34 and interlayer insulation films 36 and 33 is high is used, even if metallic film 32 (lower wiring layer) and the trench overlaps in a somewhat misaligned position. As a result, an opening can be formed in a self-aligning manner. In other words, an opening can be formed by stopper film 34 in a self-aligning manner (refer to FIG. 6).

Moreover, whereas it is not shown in FIG. 5C, when photoresist 37 is removed and then the remaining part of interlayer insulation film 36 and interlayer insulation film 33 are etched, the edge part of trench 38 becomes round as shown in FIG. 7. As a result, it becomes easy to bury copper film serving as wiring material in the trench in damascene method, for instance.

As mentioned above, according to Embodiment 5, because the time when the interlayer insulation film that is the to-be-processed material is being etched through use of photoresists 35 and 37 as masks is shortened when forming a fine trench pattern within the interlayer insulation film, photoresists 35 and 37 themselves are not etched off. As a result, there is the effect that the shape of the trench pattern is not deteriorated. In other words, photoresists 35 and 37 can be made thinner, and thereby a fine trench pattern can be easily formed.

In addition, because photoresist 37 is removed and then interlayer insulation film 36 that is the to-be-processed material is etched, the edge part of the trench pattern becomes round. As a result, there is also the effect that it becomes easy to bury wiring material in trench 38, for instance.

Moreover, as long as stopper film 34 has been formed and then stopper film 34 has been etched corresponding to the hole pattern, there is the effect that the opening can be formed by stopper film 34 in a self-aligning manner, if lower wiring layer 32 and trench 38 overlaps in a somewhat misaligned position when forming trench 38.

What is claimed is:

1. A pattern forming method used when forming a predetermined pattern within a to-be-processed material, the method comprising:
a first step of forming a resist film having a predetermined pattern shape on a to-be-processed material;
a second step of etching the to-be-processed material to a predetermined depth thereof through use of the resist film as a mask; and
a third step of removing the resist film and then further etching the to-be-processed material to form the predetermined pattern within the to-be-processed material.

2. A pattern forming method according to claim 1, wherein an etching-stopper film is provided at a predetermined depth within the to-be-processed material and in the second step the material is etched to the etching-stopper film.

3. A pattern forming method according to claim 1, wherein the to-be-processed material is partitioned into a first to-be-processed material and a second to-be-processed material; an etching-stopper film exists between the first to-be-processed material and the second to-be-processed material; in the first step a resist film is formed over the second to-be-processed material; in the second step the to-be-processed material is etched to the etching-stopper film; and in the third step the first to-be-processed material is etched.

4. A pattern forming method according to claim 2, wherein the etching stopper film is an antireflection layer and the resist film is a photoresist film.

5. A pattern forming method used when forming a predetermined pattern within a to-be-processed material having a first to-be-processed material and a second to-be-processed material formed over the first to-be-processed material, the pattern forming method comprising:
a first step of forming a resist film having the predetermined pattern shape on the second to-be-processed material;
a second step of etching the second to-be-processed material through use of the resist film as a mask to a predetermined depth thereof;
a third step of removing the resist film and then further etching the second to-be-processed material; and
a fourth step of etching the first to-be-processed material through use of the second to-be-processed material as a mask to form the predetermined pattern within the to-be-processed material.

6. A pattern forming method according to claim 5, wherein an antireflection film is formed over the second to-be-processed material, a photoresist film is used as the resist film, and the photoresist film is formed over the antireflection film.

7. A pattern forming method wherein a first pattern is formed within a first to-be-processed material, a second pattern is formed within a second to-be-processed material formed on the first to-be-processed material, and the first pattern and the second pattern are arranged to be connected, the pattern forming method comprising:
a first step of forming an etching stopper film over the first to-be-processed material;
a second step of forming a first resist film having the first pattern shape on the etching stopper film;
a third step of etching the etching stopper film through use of the first resist film as a mask;
a fourth step of removing the first resist film and then forming the second to-be-processed material over the etching stopper film;
a fifth step of forming a second resist film having the second pattern shape on the second to-be-processed material;
a sixth step of etching the second to-be-processed material to a predetermined depth thereof through use of the second resist film as a mask; and
a seventh step of removing the second resist film, then further etching the second to-be-processed material and simultaneously etching the first to-be-processed material, to thereby form the second pattern within the second to-be-processed material and form the first pattern within the first to-be-processed material.

8. A pattern forming method according to claim 7, wherein in the seventh step, an etching condition where a selective etching ratio between the first and second to-be-processed materials and the etching stopper film is higher than a predetermined selective etching ratio is used.

9. A pattern forming method according to claim 7, wherein the first pattern is a hole pattern and the second pattern is a trench pattern.
